(19) United States
(12) Patent Application Publication
(10) Pub. No.: US 2014/0320130 A1
(43) Pub. Date: Oct. 30, 2014

(54) Antenna Array for a Magnetic Resonance Tomography System

(71) Applicant: Jürgen Nistler, Erlangen (DE)

(72) Inventor: Jürgen Nistler, Erlangen (DE)

(21) Appl. No.: 14/260,458

(22) Filed: Apr. 24, 2014

(30) Foreign Application Priority Data
Apr. 25, 2013 (DE) DE 102013207582.0

(51) Int. Cl. G01R 33/36

(52) U.S. Cl. CPC G01R 33/3642
USPC 324/322

(57) ABSTRACT

An antenna array for a magnetic resonance tomography system includes a first ring with a plurality of first capacitors, a second ring with a plurality of second capacitors, and a plurality of antenna rods each extending from a region between two adjacent first capacitors to a region between two adjacent second capacitors. The antenna array enables, as a body coil, a multi-channel reception for use of modern imaging methods with a low level of technical complexity. An antenna rod of the plurality of antenna rods comprises a decoupling module configured to decouple, as required, the respective antenna rod from the remaining antenna rods of the plurality of antenna rods.

This application claims the benefit of DE 10 2013 207 582.0, filed on Apr. 25, 2013, which is hereby incorporated by reference in its entirety.

### BACKGROUND

The present embodiments relate to an antenna array for a magnetic resonance tomography system.

Magnetic resonance tomography (MRT) may be used to generate sectional images of a human (or animal) body that enable an examination of the organs and many pathological organ changes. MRT is based on very strong magnetic fields and alternating magnetic fields in the radiofrequency band, generated in an MRT system, with which certain atomic nuclei (e.g., the hydrogen nuclei/protons) in the body may be excited to resonance. As a result, an electrical signal is induced in a receiver circuit.

Magnetic resonance tomography (MRT) systems may have a signal transmitter that is provided for generating a substantially homogeneous radiofrequency field for exciting nuclear spin. The associated transmission antenna (e.g., “body coil”) may be fixedly installed in magnets and gradient coils. A design in widespread use is the “birdcage” antenna, which has a cylindrical shape and includes two rings that are connected to one another via a number of uniformly spaced-apart antenna rods arranged in parallel with one another. Connection points of the antenna rods on the rings are connected to one another via a capacitor. The capacitances of the capacitors are selected such that the antenna array is resonant at the investigation frequency (e.g., between 60 and 125 MHz).

The transmission antenna may also be used for the reception of the magnetic resonance signals. Since the transmission antenna may be configured for circular polarization in this case, however, a maximum of two reception channels are available. Modern imaging methods use techniques for reducing the measurement time such as, for example, SENSE or GRAPPA, which are ultimately based on omitting individual rows of the so-called k space in measurement. The missing information for the image calculation in this case is to be obtained again from a large number of reception coils with different field profiles. Therefore, such methods may not be used when using the body coil as reception antenna.

For this reason, a multi-channel array of reception antennas close to the patient is used. The reception antennas are also referred to as local coils. This enables a parallel measurement (e.g., more than 16 channels) with a good signal-to-noise ratio. The attachment of the local coils to the subject under investigation (e.g., to the patient) and the routing of the reception signals to the patient couch is undesirable owing to the complicated wiring, however.

Therefore, a fixedly installed reception antenna array includes very low-noise antenna elements using a “remote body array.” This array has a very good signal-to-noise ratio. The radial installation space for a cylindrical remote body array is restricted radially inwards, however, since a patient opening that is as large as possible is desired. Relatively large diameters of the magnet or the gradient systems result in severely increasing costs, however. In addition, there are stringent requirements on the infrastructure with respect to cooling, wiring and space requirement.

The body coil may be configured as a combined transmission and reception antenna with a multichannel design. This results in an acceptable signal-to-noise ratio and does not result in any additional space requirement. By arranging a capacitor in the antenna rods in the case of the birdcage antenna, the antenna rods become independent antenna elements each provided with a dedicated transmission/reception switch.

### SUMMARY AND DESCRIPTION

The scope of the present invention is defined solely by the appended claims and is not affected to any degree by the statements within this summary.

The independent antenna elements are to be actuated individually during transmission operation (e.g., by individual amplifiers or by a single amplifier with a corresponding power divider). In the prior art, this results in considerable complexity with respect to the infrastructure and calibration of antenna and therefore comparatively high costs.

The present embodiments may obviate one or more of the drawbacks or limitations in the related art. For example, an antenna array that, as a body coil, enables multi-channel reception for use of modern imaging methods with a small amount of technical complexity is provided.

An antenna rod having a decoupling module configured to decouple, as required, the respective antenna rod from the remaining antenna rods is also provided.

In this case, one or more of the present embodiments are based on the consideration that, for a simple and inexpensive technical configuration of the body coil antenna array, actuation with a single amplifier and a signal generator may be provided. Therefore, the body coil may be useable as conventional transmission antenna with circular polarization. For reception, the individual antenna rods may be made such that the individual antenna rods are useable independently of one another as individual reception channels, however. This may be achieved via a decoupling module being arranged in the antenna rod to be used in each case as an individual reception channel. The decoupling module may decouple the antenna rod from the remaining antenna rods. Such a decoupling module may be provided in each antenna rod, with the result that the body coil, if necessary, may be decoupled in a completely degenerated birdcage, and each antenna rod may form a dedicated reception channel.

In the case of an antenna array configured for transmission and reception, the decoupling module is configured to decouple the antenna rod during reception and to couple the antenna rod during transmission. For this, for example, a control device that synchronizes the decoupling of the respective antenna rod with the signal transmitter itself or a switch arranged between the signal transmitter and the antenna array may be provided. During transmission operation, coupling of the antenna rods is thus present, and is only decoupled in a targeted manner at times without transmission operation.

The decoupling module has a capacitance that compensates for the inductance for the respective antenna rod, as required. The capacitance may be realized by one or more capacitors. As a result, decoupling of the respective antenna rod is provided in a manner that is particularly simple and reliable in technical terms.

In one configuration, the capacitance is connected in parallel with a switchable resistor into the antenna rod. By switching over the resistor in the high-resistance or low-resistance state, the capacitive effect may be connected or disconnected particularly easily. In the low-resistance state of the resistor, the capacitance (e.g., a capacitor) is bridged. In the high-resistance state, the bridging path is blocked, and the capacitive effect of the capacitor gives the desired effect compensating for the inductance of the antenna rod.

In a further configuration, the decoupling module includes a reception module with a signal output. As a result, the relevant signal may be picked up directly at the respective antenna rod, which is useful as a decoupled reception channel in the configuration described. The signal output may be coupled to the capacitance, which is connected to the antenna rod, if required, for example.

Under certain circumstances, passing the signals out in the central region of the antenna rods may be technically too complex. Precisely when conversion of an already existing system is intended to take place, in this case, there may be no possibility of passing out signals without extensive adaptations. In this case, the reception signals may be passed out at one of the rings of the body coil via a reception module, which may be connected, as required, and has a signal output, being associated to one of the capacitors adjacent to the respective antenna rod.

In one embodiment, the reception module is configured to be connected during reception. If, as described above, a control device that synchronizes the decoupling of the respective antenna rod with the signal transmitter itself or a switch arranged between the signal transmitter and the antenna array is provided, the reception module is likewise also synchronized. As a result, the reception module is deactivated during transmission operation and is only activated during reception operation.

In an advantageous configuration, the reception module has a switchable resistor that is connected in parallel with the capacitor in one of the rings. By switching over the resistor to the high-resistance or low-resistance state, the reception module may be connected or disconnected particularly easily. In the low-resistance state of the resistor, the line path into the reception module becomes free. In the high-resistance state, the line path into the reception module is blocked, and only the capacitive effect of the capacitor provides the intended effect.

In one configuration, the respective switchable resistor includes a pin diode. A pin diode has the same response as an ohmic resistor at the high frequencies that are used in MRT. The pin diode is also actuable in a particularly simple manner via direct current.

In one embodiment, the respective reception module includes a preamplifier that is connected upstream of the signal output and a matching network for the preamplifier. As a result, the reception signal is already conditioned in the reception module, with the result that optimized signal output may take place. The signal-to-noise ratio is improved.

In one embodiment, a magnetic resonance tomography system includes the described antenna array.

The advantages achieved by one or more of the present embodiments include, for example, that via the decoupling of the individual antenna rod of the birdcage body coil in an MRT system, which decoupling is, if necessary, synchronized with transmission and reception phases, the use of modern parallel imaging methods without the technical complexity of the prior art is provided. The described array may be integrated in the system without the user or patient noticing since the antenna array is permanently installed in the system. In comparison with the multichannel solutions that are known to date (e.g., multichannel body coils or distal reception arrays), there are virtually no additional requirements with respect to the infrastructure. As a result, the solution may be realized at low cost.

In one embodiment, conventional methods for monitoring the patient safety such as monitoring of the specific absorption rate (SAR) may still be used with only two directional couplers. The reception in the circular polarized mode, for example, for the adjustment still remains possible since, if necessary, the circular polarized mode in the reception mode may be switched to. The array also enables preamplification directly at the end ring of the antenna array, which improves the signal-to-noise ratio.

### BRIEF DESCRIPTION OF THE DRAWINGS

FIG. 1 shows one embodiment of a birdcage antenna array including antenna rods that may be decoupled, as required;

FIG. 2 shows one embodiment of a decoupling module of the birdcage antenna array with integrated reception module;

FIG. 3 shows a further embodiment of a birdcage antenna array with antenna rods that may be decoupled, as required, with signal outputs at the end ring;

FIG. 4 shows one embodiment of a decoupling module of the further birdcage antenna array; and

FIG. 5 shows one embodiment of a reception module of the further birdcage antenna array in the end ring.

### DETAILED DESCRIPTION

The same parts have been provided with the same reference symbols in all of the figures.

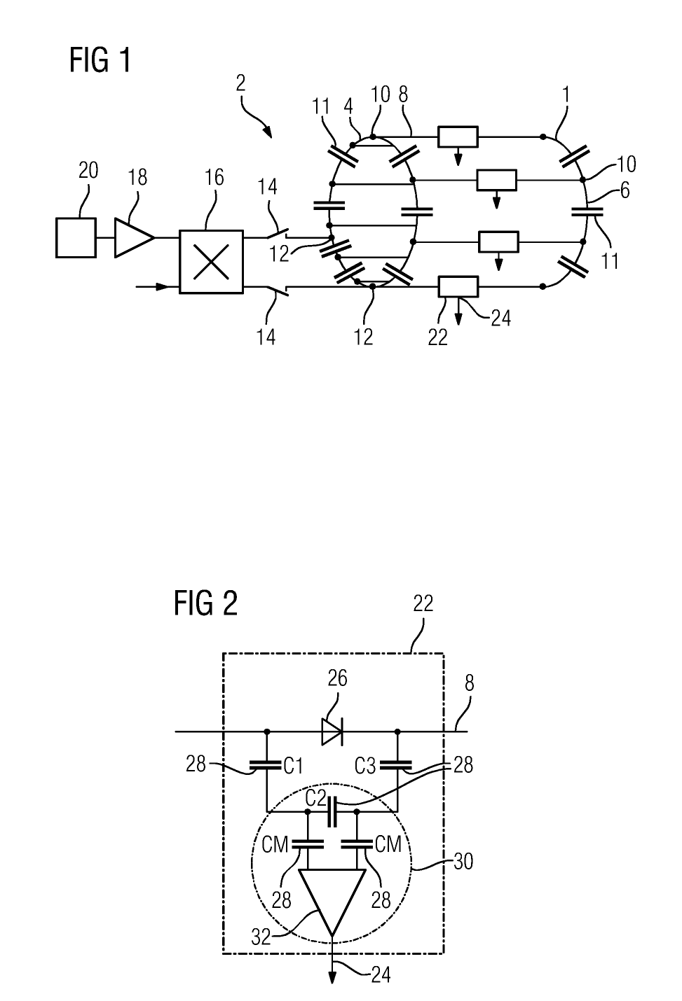

FIG. 1 shows one embodiment of an antenna array 1 that is configured as a birdcage body coil and is arranged in magnetic resonance tomography (MRT) system 2. The remaining parts of the MRT system 2, such as magnets, patient couch, etc., are not illustrated for reasons of clarity. The antenna array 1 includes a first electrically conductive ring 4 and a second electrically conductive ring 6 (e.g., rings), which form a bottom surface and a top surface of a horizontal cylinder. The patient to be examined is pushed into the cylinder during the MRT examination.

Between the rings 4, 6, antenna rods 8 extend in a radial direction from the first ring 4 to the second ring 6. The antenna rods 8 are connected to the respective rings 4, 6 at connection points 10 that are arranged at regular intervals along the circumference of the cylinder. In each case, one capacitor 11 is arranged between adjacent connection points 10. The capacitances of the capacitors 11 are in this case selected such that resonance exists at the intentional examination frequency in the antenna array 1, together with the inductance of the antenna rods 8. The examination frequency is in this case in the range of from 60 to 125 MHz.

Two connection points 12 for the input signal are arranged on the first ring 4. The connection points are shifted through 90° on the ring 4. The connection points are connected to the outputs of a phase-shifting element 16 via switch 14. The phase-shifting element 16 effects a phase shift of the input signal through 90° and has a predetermined admittance. For this, the phase-shifting element 16 is in the form of a 90° hybrid coupler.

On the input side, the phase-shifting element 16 is connected on a first channel to a terminating resistance of 50 ohms. On a second channel, the phase-shifting element 16 is connected via an amplifier 18, to a signal generator 20 that is suitable for generating radiofrequency signals. The described antenna circuit is therefore suitable for generating circular polarization. Alternatively, a simple feed with linear polarization may also be provided.

The amplifier 18 is in the form of a radiofrequency power amplifier (RFPA), which substantially multiplies the amplitude of the radiofrequency input signal of the signal generator 20.

Previous birdcage body coils with the described design could also form at most two channels in the reception case if the antenna array 1 was likewise intended for reception, and no separate reception coils were provided in the MRT system. For the reception, these switches 14 were opened, as required, and the signal was picked up from the antenna array 1 at the switches 14 and processed.

The antenna array 1 shown in FIG. 1, however, is suitable for multichannel reception operation. For this purpose, a decoupling module 22 is connected into each antenna rod 8 approximately centrally. In FIG. 1, the decoupling modules 22 each have a signal output 24.

An embodiment of one of the decoupling modules 22 with a circuit is shown in FIG. 2. Two parallel line paths are connected into the antenna rod 8. The first line path has a pin diode 26. The design of the pin diode 26 is similar to a pin diode, with the difference that an additional week or undoped layer is located between the p-doped and n-doped layers. Above 10 MHz, the pin diode 26 therefore has the same response as an ohmic resistance, which is inversely proportional to the average current through the pin diode 26. As a result, the pin diode 26 acts a resistor that is switchable by direct current at the frequencies used in the MRT system 2 of over 60 MHz. The actuation of the pin diode 26 is not illustrated in FIG. 2 or in the following figures for reasons of clarity.

In the second parallel line path of the decoupling module 22, three capacitors 28 are connected in series. The capacitances of the capacitors are denoted by C1, C2, C3 in FIG. 2. The capacitances C1, C2, C3 form a total capacitance that may precisely compensate for the inductance of the antenna rod 8.

Each decoupling module 22 includes a reception module 30. The reception module 30 includes a preamplifier 32 with the signal output 24. On the input side, the preamplifier 32 is connected to two branches between the capacitances C1 and C2 and C2 and C3 via two capacitors 28 with the capacitances CM. The capacitances C2 and CM therefore form a matching network for the preamplifier 32.

The way in which the antenna array 1 works will be explained below. The actuation of the described components is performed by a control device, such as, for example, a personal computer that is not shown in any more detail for reasons of clarity.

The antenna array 1 has a transmission and a reception operating mode. In the transmission mode, the switches 14 are closed, and the pin diodes 26 are in the low-resistance state. The capacitances of the capacitors 28 in the decoupling module are negligible, with the result that tuning of the antenna is performed substantially via the capacitors 11 in the rings 4, 6. The antenna array 1 therefore acts as a conventional transmission antenna with a high-pass birdcage design with circular polarization.

In the reception mode, the switches 14 are opened, and the pin diodes 26 are switched to the high-resistance state. The antenna array 1 therefore becomes the degenerated birdcage. The capacitances C1, C2, C3 are relevant owing to the high-resistance state of the pin diodes 26 and provide compensation of the inductance of the antenna rods 8 and therefore decoupling of the now resulting adjacent antenna elements. Each antenna rod 8 forms such an independent antenna element. The signals of these antenna elements are picked up by the reception module 30, amplified and output to the signal outputs 24.

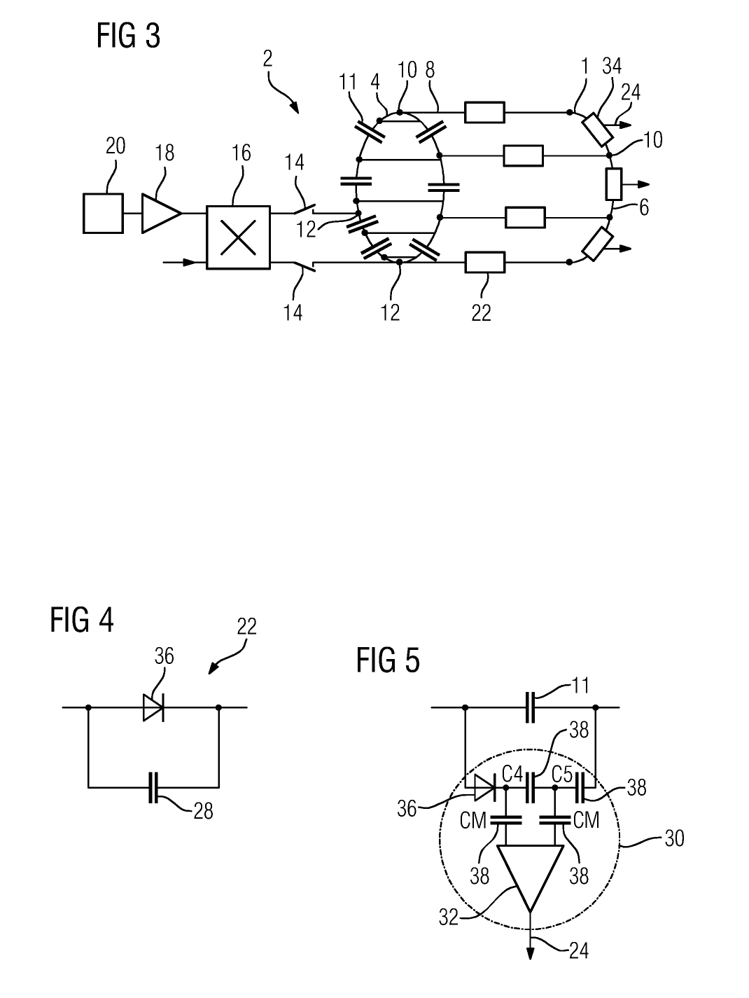

An alternative embodiment is shown in FIGS. 3, 4, and 5. FIG. 3 will be explained below only in terms of differences with respect to FIG. 1. The switches 14 and all of the components connected upstream thereof are the same as FIG. 1 and are therefore not shown. The decoupling modules 22 do not have signal outputs 24. Instead, the capacitors 11 in the ring 6 are replaced by circuits 34 with signal outputs 24.

In the alternative embodiment, the decoupling modules 22 are arranged the same but have a simpler design, as shown in FIG. 4. The decoupling modules 22 include a parallel circuit including a pin diode 26 and a capacitor 28 that is connected into the respective antenna rod 8. The operation is the same (e.g., the decoupling modules 22 provide decoupling, as required, of the antenna rods 8 by virtue of the capacitance of the capacitor 28 being selected such that the capacitance of the capacitor 28 compensates for the inductance of the respective antenna rod 8). The decoupling modules 22 shown in FIGS. 3 and 4 do not have a reception module 30.

Instead, the reception modules 30 are integrated in circuits 34 in the ring 6, as shown in FIG. 5. Two parallel line paths are connected into the ring 6. The first line path has a capacitor 11. In the second parallel line path of the circuit 34, a pin diode 36 and two capacitors 38 are connected in series. The capacitances of the capacitors are denoted by C4 and C5 in FIG. 2. The actuation of the pin diode 36 is again not shown.

Each circuit 34 includes a reception module 30. The reception module 30 includes a preamplifier 32 with the signal output 24. On the input side, the preamplifier 32 is connected via two capacitors 38 with the capacitances CM to two branches between the pin diode 36 and the capacitance C4 or capacitances C4 and C5. The capacitances C4 and CM therefore form a matching network for the preamplifier 32.

The mode of operation is similar to the mode of operation for the embodiment described in FIGS. 1 and 2. In the reception case, the pin diode 36 is switched to the low-resistance state, with the result that the reception module 30 in the circuit 34 may pick up the signal of the respectively associated antenna rod 8, amplify the signal, and output the signal at the signal output 24. In this case, the signals are therefore picked up at the ring 6, which may have design advantages in comparison with the embodiment shown in FIGS. 1 and 2.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. An antenna array for a magnetic resonance tomography system, the antenna array comprising:
a first ring comprising a plurality of first capacitors; and
a second ring comprising a plurality of second capacitors and a plurality of antenna rods, each antenna rod of the plurality of antenna rods extending from a region between two adjacent first capacitors to a region between two adjacent second capacitors,
wherein an antenna rod of the plurality of antenna rods comprises a decoupling module configured to decouple the respective antenna rod from the remaining antenna rods of the plurality of antenna rods.

2. The antenna array of claim 1, wherein the antenna array is configured for transmission and reception, and
wherein the decoupling module is configured to decouple the antenna rod during reception and to couple the antenna rod during transmission.

3. The antenna array of claim 1, wherein the decoupling module comprises a capacitance operable to compensate for an inductance of the respective antenna rod.

4. The antenna array of claim 3, wherein the capacitance is connected in parallel with a switchable resistor into the antenna rod.

5. The antenna array of claim 1, wherein the decoupling module comprises a reception module, the reception module comprising a signal output.

6. The antenna array of claim 1, further comprising a reception module that is connectable to the antenna array and comprises a signal output, the reception module being assigned to one capacitor of the plurality of first capacitors and the plurality of second capacitors adjacent to the respective antenna rod.

7. The antenna array of claim 6, wherein the antenna array is configured for transmission and reception,
wherein the decoupling module is configured to decouple the antenna rod during reception and to couple the antenna rod during transmission, and
wherein the reception module is configured to be connected during reception.

8. The antenna array of claim 6, wherein the reception module comprises a switchable resistor that is connected in parallel with the capacitor.

9. The antenna array of claim 7, wherein the reception module comprises a switchable resistor that is connected in parallel with the capacitor.

10. The antenna array of claim 4, wherein the respective switchable resistor comprises a pin diode.

11. The antenna array of claim 8, wherein the respective switchable resistor comprises a pin diode.

12. The antenna array of claim 5, wherein the respective reception module comprises a preamplifier connected upstream of the signal output.

13. The antenna array of claim 12, wherein the respective reception module comprises a matching network.

14. A magnetic resonance tomography system comprising:
an antenna array comprising:
a first ring comprising a plurality of first capacitors; and
a second ring comprising a plurality of second capacitors and a plurality of antenna rods, each antenna rod of the plurality of antenna rods extending from a region between two adjacent first capacitors to a region between two adjacent second capacitors,
wherein an antenna rod of the plurality of antenna rods comprises a decoupling module configured to decouple, as required, the respective antenna rod from the remaining antenna rods of the plurality of antenna rods.

15. The magnetic resonance tomography system of claim 14, wherein the antenna array is configured for transmission and reception, and
wherein the decoupling module is configured to decouple the antenna rod during reception and to couple the antenna rod during transmission.

16. The magnetic resonance tomography system of claim 14, wherein the decoupling module comprises a capacitance operable to compensate for an inductance of the respective antenna rod.

17. The magnetic resonance tomography system of claim 16, wherein the capacitance is connected in parallel with a switchable resistor into the antenna rod.

18. The magnetic resonance tomography system of claim 14, wherein the decoupling module comprises a reception module, the reception module comprising a signal output.

19. The magnetic resonance tomography system of claim 14, wherein the antenna array further comprises a reception module that is connectable to the antenna array and comprises a signal output, the reception module being assigned to one capacitor of the plurality of first capacitors and the plurality of second capacitors adjacent to the respective antenna rod.

20. The magnetic resonance tomography system of claim 19, wherein the antenna array is configured for transmission and reception,
wherein the decoupling module is configured to decouple the antenna rod during reception and to couple the antenna rod during transmission, and
wherein the reception module is configured to be connected during reception.
